(19) United States
(12) Patent Application Publication
(10) Pub. No.: US 2007/0080750 A1
(43) Pub. Date: Apr. 12, 2007

(54) High efficiency amplifiers having multiple amplification paths

(75) Inventor: John Liebenrood, Hillsboro, OR (US)

Correspondence Address: KLARQUIST SPARKMAN, LLP, 121 SW SALMON STREET, SUITE 1600, PORTLAND, OR, 97204, US

(73) Assignee: TriQuint Semiconductor, Inc.

(21) Appl. No.: 11/217,698

(22) Filed: Aug. 31, 2005

(51) Int. Cl. H01Q 11/12; H03F 3/45; H04B 1/04

(52) U.S. Cl. 330/252; 455/127.2

(57) ABSTRACT

Described herein are representative embodiments of amplifiers having multiple amplification paths. In certain exemplary embodiments, the amplifiers are operated as linear power amplifiers, such as may be used in wireless communications systems. In one exemplary embodiment, an amplifier circuit is described comprising switchless amplification paths coupled in parallel to one another. In this exemplary embodiment, the amplification paths comprise amplifier sections that are activated substantially exclusively of one another.

### TECHNICAL FIELD

The present application relates generally to amplifiers, such as power amplifiers as may be used to amplify radio frequency (RF) signals.

### BACKGROUND

In the past two decades, the market for wireless communication systems has shown unprecedented growth. In addition to the widespread proliferation of mobile phone services, wireless local area networks (WLANs) operating according to wireless standards such as IEEE 802.11a, IEEE 802.11b, and IEEE 802.11g are becoming more common. As the popularity of wireless systems increases, so does the demand for improved performance in the wireless transceivers supporting such systems.

One of the components in a wireless transceiver that can affect performance is the power amplifier. For example, linear power amplifiers are often used in mobile transceivers to amplify radio frequency (RF) signals to be transmitted from the transceiver. Linear amplification is typically required in such transceivers to support the signal processing methods used to encode the RF transmissions (for example, Code Division Multiple Access (CDMA) or Enhanced Data GSM Environment (EDGE) processing). Further, because of the mobile nature of many wireless devices, the power amplification required for proper transmission is not necessarily constant. Consider, for example, a typical CDMA handset used in a cellular telephone network. Typical CDMA handsets are desirably capable of producing output powers of up to +28 dBm. The average output power that is necessary for such handsets, however, is far less than this maximum, and is generally closer to 0 dBm. The power required for proper transmission is typically dependent on the distance of the handset to the corresponding base station, and thus varies as the handset is transported from location to location. Further, because the typical handset draws its power from the handset battery, efficient operation of the linear power amplifier at the various required power levels extends battery life, and thus the talk time of the handset.

Accordingly, there exists a need for improved amplifiers that are compact and that can operate with enhanced efficiency in multiple power modes, thereby providing the high-power power in one mode and efficient, low-power operation in another.

### BRIEF DESCRIPTION OF THE DRAWINGS

FIG. 1 is a schematic block diagram of an amplifier section in accordance with a first exemplary embodiment of the disclosed technology.

FIG. 2 is a more specific schematic block diagram of an exemplary implementation of the amplifier section illustrated in FIG. 1.

FIG. 3 is a more specific schematic block diagram of another exemplary implementation of the amplifier section illustrated in FIG. 1.

FIG. 4 is a schematic block diagram of an amplifier section in accordance with a second exemplary embodiment of the disclosed technology.

FIG. 5 is a more specific schematic block diagram of an exemplary implementation of the amplifier section illustrated in FIG. 4.

### DETAILED DESCRIPTION

As used in this application and in the claims, the singular forms “a,” “an,” and “the” include the plural forms unless the context clearly dictates otherwise. Additionally, the term “includes” means “comprises.” Further, the term “coupled” means electrically or electromagnetically connected or linked and does not exclude the presence of intermediate elements between the coupled items.

Disclosed below are representative embodiments of an amplifier circuit that may be used, for example, as part of a wireless communication system. For example, any of the disclosed embodiments can be used as an amplifier stage (for example, a final amplifier stage) in an RF transceiver front end as may be used in a mobile handset, such as a CDMA or GSM handset. Also disclosed herein are exemplary methods by which the embodiments can operate or be operated. Exemplary environments and applications for the disclosed embodiments are also disclosed. For example, the disclosed embodiments can be used in a variety of applications that involve the amplification of RF signals over a range of power levels. The described systems, apparatus, and methods should not be construed as limiting in any way. Instead, the present disclosure is directed toward all novel and nonobvious features and aspects of the various disclosed embodiments, alone and in various combinations and sub-combinations with one another. The disclosed systems, methods, and apparatus are not limited to any specific aspect or feature or combination thereof, nor do the disclosed systems, methods, and apparatus require that any one or more specific advantages be present or problems be solved.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. For example, although any of the disclosed embodiments may be implemented as part of an RF transceiver in a wireless communication system (for example, in a cellular telephone handset, such as a CDMA handset), other components of the RF transceiver are well known in the art and are not described in further detail. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

The disclosed embodiments can be implemented in a wide variety of circuits and systems (for example, application-specific integrated circuits (ASICs), systems-on-a-chip (SOCs), systems in a package (SIPs), systems on a package (SOPs), multi-chip modules (MCMs), or other such devices). The various components of the disclosed embodiments can be implemented (separately or in various combinations and subcombinations with one another) using a variety of different semiconductor materials, including but not limited to: gallium arsenide (GaAs) and GaAs-based materials (AlGaAs, InGaAs, AlAs, InGaAlAs, InGaP, InGaNP, AlGaSb, and the like); indium phosphide (InP) and InP-based materials (InAlP, InGaP, InGaAs, InAlAs, InSb, InAs, and the like); silicon (Si), strained silicon, germanium (Ge) and silicon- and germanium-based materials (SiGe, SiGeC, SiC, SiO₂, high dielectric constant oxides, and the like) such as complementary metal-oxide-semiconductor (CMOS) processes; and gallium nitride materials (GaN, AlGaN, InGaN, InAlGaN, SiC, Sapphire, Si, and the like).

In certain embodiments, the amplifier section is implemented on a single chip. The disclosed embodiments can also be implemented using combinations of these process technologies (for example, on multiple chips or on a single chip). The disclosed embodiments can also be implemented using a variety of different off-chip processes, including but not limited to low- or high-frequency printed circuit board (PCB) processes, thick- or thin-film hybrid processes, multi-layered organic processes, and low-temperature cofired ceramic (LTCC) processes.

Similarly, a variety of transistor technologies can be used to implement the disclosed embodiments. For example, the disclosed amplifier embodiments can be implemented using bipolar junction transistor (BJT) technologies (for example, heterojunction bipolar junction transistors (HBTs)) or field effect transistor (FET) technologies (for example, pseudomorphic high electron mobility transistors (pHEMTs)). Combinations or subcombinations of these technologies or other transistor technologies can also be used to implement the disclosed circuit embodiments. Such combinations may be implemented on multiple chips or a single chip. For example, any of the disclosed embodiments can be implemented on a single chip using a combination of HBTs and pHEMTs.

The example amplifier sections and control systems can be included in a variety of electronic devices. For example, any of the amplifier embodiments described herein can be implemented as part of an amplifier module used in mobile devices such as cell phones, personal digital assistants, mobile media players, laptop computers, and pagers to provide improved battery life. Devices based on wireless standards such as 802.11a, 802.11b, 802.11g, 802.16, and BLUETOOTH may also include such amplifier modules. Other devices (both fixed and mobile) that use wireless communications such as keyboards, pointing devices, media distribution devices, and desktop computers can also include such amplifier modules. In a representative example, a cell phone or mobile station can include a control circuit (for example, a baseband processor) configured to provide a power-mode-control signal or high/low-control signal to select an operational mode of an amplifier section as disclosed herein that includes multiple amplification paths. Other wireless devices can be similarly configured. Other applications for the disclosed embodiments include WLAN systems, wireless systems using TDMA or EDGE modulation techniques, and other such systems.

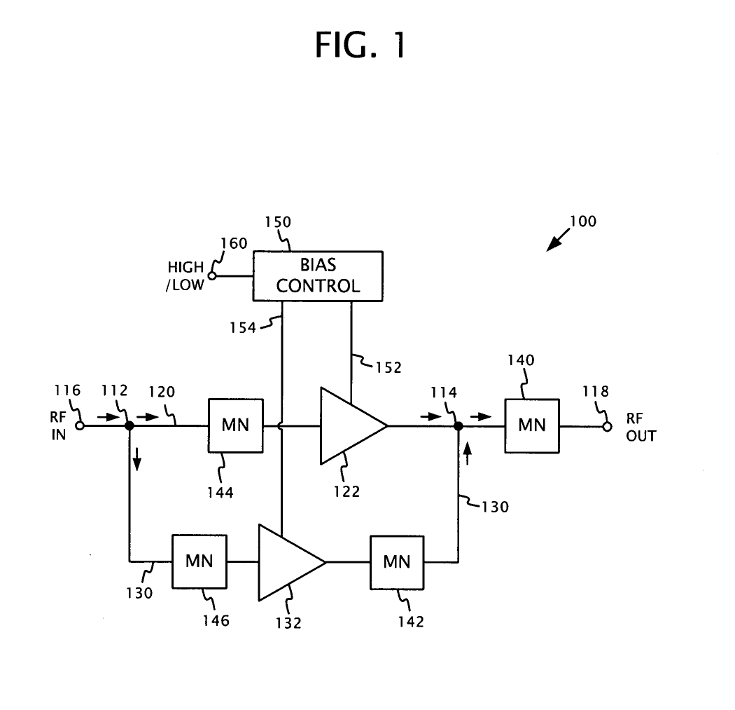

FIG. 1 is a schematic block diagram illustrating an exemplary amplifier section 100 according to the disclosed technology. The amplifier section 100 comprises a first amplification path 120 coupled between a first node 112 and a second node 114, and a second amplification path 130 also coupled between the first node 112 and the second node 114. In the illustrated embodiment, the first node 112 is coupled to an input node 116, which is configured to receive an input signal (for example, an RF signal). In some embodiments, for example, the input node 116 is coupled to a prior amplification stage (for instance, a variable gain amplifier (VGA)). Similarly, the second node 114 is coupled to an output node 118, which is configured to drive a downstream load (for example, an RF antenna section). In operation, a signal that is input at the input node 116 desirably propagates through the amplifier section 100 to the output node 116. For purposes of this disclosure, respective ends of a path or a circuit element are sometimes identified relative to this desired direction of signal propagation along the paths of the amplifier section (shown by arrows in the corresponding figures). Thus, the “upstream” end of a path or circuit element refers to the end at which a signal desirably begins, whereas the “downstream” end of a path or element refers to the end to which the signal desirably propagates.

The first amplification path 120 includes a first amplifier subsection 122 comprising one or more amplifiers. For example, the first amplifier subsection 122 can comprise multiple transistors coupled in parallel to one another, transistors coupled in series to one another, or a combination of both. The transistors in the first amplifier subsection 122 can be operated (individually or in combination with one another) as linear amplifiers (for example, as class AB or deep class AB amplifiers approaching class B amplifiers) or as saturated amplifiers (for example, as class D, E, or F amplifiers). For ease of description, the disclosed embodiments are understood to be linear amplifiers unless otherwise stated. Any of the disclosed embodiments, however, can be adapted for operation as saturated amplifiers such as may be used, for example, in GSM power amplifiers. In certain embodiments, the first amplifier subsection 122 comprises multiple parallel-connected heterojunction bipolar transistors (HBTs).

The second amplification path 130 includes a second amplifier subsection 132 also comprising one or more amplifiers as described above. For example, the second amplifier subsection 132 can comprise multiple transistors coupled in parallel to one another, transistors coupled in series to one another, or a combination of both. In some embodiments, the second amplifier subsection 132 comprises one HBT, whereas in other embodiments the second amplifier subsection 132 comprises two serially coupled HBTs or multiple parallel-connected HBTs.

In the illustrated embodiment, the second amplifier subsection 132 is configured to produce a smaller power gain than the first amplifier subsection 122. For example, the first amplifier subsection 122 may comprise M parallel-connected transistors, and the second amplifier subsection 132 may comprise N parallel-connected transistors, where M>N so that the second amplifier subsection 132 consumes less power in operation than the first amplifier subsection 122. For this reason, the second amplifier subsection 132 is sometimes referred to herein as the “low-power amplifier subsection” and the amplification path 130 is sometimes referred to as the “low-power amplification path.” Similarly, the first amplifier subsection 122 is sometimes referred to as the “high-power amplifier subsection,” and the amplification path 120 is sometimes referred to as the “high-power amplification path.”

In some embodiments, the high-power amplifier subsection 122 and the low-power amplifier subsection 132 are configured to operate in multiple power modes to provide different levels of power gain and power consumption. For example, the amplifier subsections 122, 132 may be controllable via one or more respective control signals 152, 154 provided by a bias control system 150. The bias control system 150 can operate the amplifier subsections 122, 132 in multiple modes of operation, such as a high-power mode and a low-power mode. The bias control system 150 can be configured, for instance, to apply a predetermined or variable DC bias voltage on the control lines 152, 154 to transistors of the respective amplifier subsections 122, 132 (for example, to respective bases of the transistors in the amplifier subsection s 122, 132).

In the illustrated implementation, for example, the bias control system 150 applies predetermined bias voltages in response to a single-bit control signal (“HIGH/LOW”) received at control node 160. According to one particular implementation, the high-power amplifier subsection 122 is enabled and the low-power amplifier subsection 132 is disabled by the control system 150 in a high-power mode operation (for example, when the HIGH/LOW control signal is high). By contrast, during a low-power mode, the high-power amplifier subsection 122 is disabled and the low-power amplifier subsection 132 is enabled by the control system 150 (for example, when the HIGH/LOW control signal is low). The HIGH/LOW control signal can be received, for example, from an associated control system (not shown) of an electronic device in which the amplifier section 100 is implemented. For example, in embodiments in which the amplifier section 100 is used as a power amplifier in a mobile handset, the HIGH/LOW control signal can be provided from an associated baseband processor of the handset.

In certain embodiments, the amplifier section 100 is configured to operate in low-power mode when the desired output power from the amplifier section 100 (in combination with any early amplifier stages) is less than or substantially equal to +18 dBm, and to operate in high-power mode when the desired output power is substantially equal to or greater than +18 dBm. In particular implementations, the amplifier section 100 is part of a power amplifier module configured to produce a maximum output power of about +28 dBm.

As more fully explained below, an amplifier subsection (or amplification path) is termed “disabled” when it is operated so that its associated amplification path does not provide power amplification to an input signal coupled to the path. One or more of the transistors in the respective amplifier subsections 122, 132 may nevertheless be biased into the respective transistor's active or saturation region even though the respective amplifier subsection (or amplification path) is disabled. For example, two or more of the transistors in the low-power amplifier subsection 132 can be serially coupled together to form a combination transistor configuration (such as a cascode configuration) wherein at least one of the transistors is biased off and at least one of the other transistors is biased into saturation mode when the low-power amplifier subsection 132 is disabled. As more fully explained below, this type of configuration and amplifier operation can help improve the reverse isolation characteristics and overall stability of the amplifier section 100. As another example, the low-power amplifier subsection can be coupled between two matching networks configured to operate substantially as impedance inverters. During operation, one or more of transistors in the low-power amplifier subsection 132 can be biased into saturation when the low-power amplifier subsection is disabled (for example, during high-power operation). In saturation, the transistors can create a low impedance that is transformed by the impedance inverters into respective high impedances seen at the ends of the low-power amplification path 130.

The illustrated amplifier section 100 further comprises a first impedance matching network 140 coupled between the second node 114 and the output node 118. In general, the first impedance matching network 140, or any impedance matching network described herein, is configured to transform the impedance at one end of the network to a different impedance at the opposite end of the network. For example, in the illustrated embodiment, the first impedance matching network 140 is configured to substantially match the impedance of the load at the output node 118 during high-power operation. In a particular implementation, the output node 118 drives a 50 Ohm load and the high-power amplifier subsection 122 desirably drives a 4 Ohm load during high-power operation. Accordingly, in this implementation, the first impedance matching network 140 is configured to transform the impedance from a 50 Ohm load to a 4 Ohm load during high-power operation (when the low-power amplification subsection 132 is disabled).

The illustrated amplifier section 100 further comprises a second impedance matching network 142 coupled between the second node 114 and the output of the low-power amplifier subsection 122. In the illustrated embodiment, the second impedance matching network 142 is configured to transform the impedance at its downstream end into a higher impedance during low-power operation. For instance, according to one exemplary embodiment, the second impedance matching network 142 can be configured to transform a 4 Ohm impedance into a 50 Ohm impedance at its upstream end when the amplifier section 100 is operating in low-power mode (when the high-power amplifier subsection 122 is disabled).

The illustrated amplifier section 100 further comprises a third impedance matching network 144 coupled between the first node 112 and the input of the high-power amplifier subsection 122. In the illustrated embodiment, the third impedance matching network 144 is configured to substantially match the impedance at the input of the high-power amplifier subsection 122 with the impedance at the first node 112 during high-power operation and to transform the impedance at its downstream end into a higher impedance at its upstream end during low-power operation.

The illustrated amplifier section 100 additionally comprises a fourth impedance matching network 146 coupled between the first node 112 and the input of the low-power amplifier subsection 132. In the illustrated embodiment, the fourth impedance matching network 146 is configured to substantially match the impedance at the input of the low-power amplifier subsection 132 with the impedance at the first node 112 during low-power operation and to transform the impedance at its downstream end into a higher impedance at its upstream end during high-power operation.

The impedance matching networks 140, 142, 144, 146 (or any impedance matching network described herein) can be implemented using a variety of different components and according to a variety of different configurations. For example, the impedance matching networks 140, 142, 144, 146 can be implemented using combinations of inductance and capacitance elements. In particular embodiments, for example, at least some of the impedance matching networks 140, 142, 144, 146 are implemented using series-L and shunt-C elements (for instance, one or more shunt-C series-L networks). One, some, or all of the impedance matching networks 140, 142, 144, 146 can also be configured to operate substantially as an impedance inverter. An impedance inverter can generally be characterized as a circuit portion configured to produce an impedance at one end of the circuit portion that is inversely related to an impedance at the other end of the circuit portion. For example, an impedance inverter can be configured to operate substantially in accordance with the equation Z_{O}²=Z_{IN}×Z_{OUT}, where Z_{O} is the characteristic impedance of the impedance inverter, Z_{IN} is the impedance at the input of the impedance inverter, and Z_{OUT} is the load impedance at the output of the impedance inverter. A matching network configured to operate substantially as an impedance inverter can be implemented using a quarter wavelength transmission line or lumped circuit equivalents, such as any of the LC networks described above.

In the illustrated embodiment, no switches are used along the low-power and high-power amplification paths 120, 130. Instead, the selective biasing of the amplifier subsections 122, 132 is used to direct the input signal through the amplifier section 100 and along one of the respective amplification paths. Consequently, the hardware overhead used to implement the amplifier section 100 is small, thereby allowing the architecture to be implemented in a small area. For example, embodiments of the amplifier section 100 (or any amplifier embodiment disclosed herein) can be implemented as part of a 4×4-mm² or 3×3-mm² power amplifier module, such as a CDMA or GSM power amplifier module.

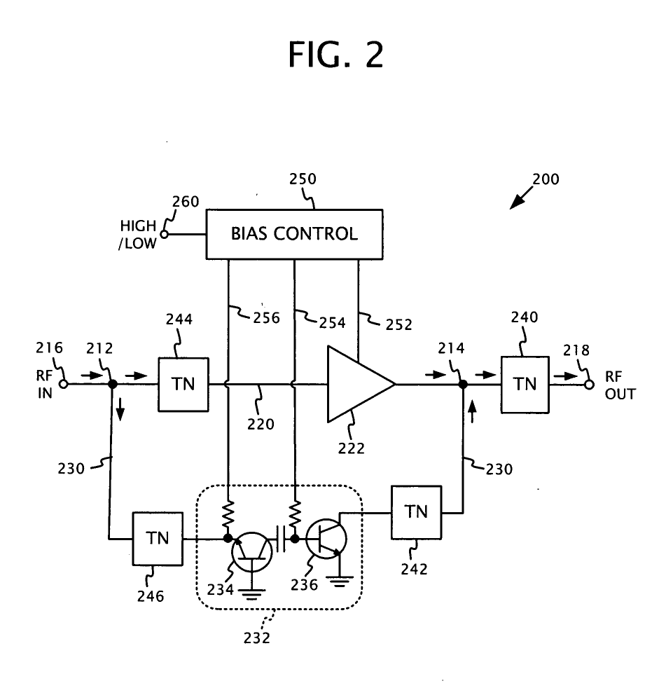

FIG. 2 is a schematic block diagram showing a more specific implementation of the exemplary amplifier section 100 described above with respect to FIG. 1. In particular, FIG. 2 shows an amplifier subsection 200 comprising a high-power amplification path 220 coupled between a first node 212 and a second node 214, and a parallel low-power amplification path 230 also coupled between the first node 212 and the second node 214. In the illustrated embodiment, the first node 212 comprises a three-port node coupled to an input node 216 for receiving an input signal (for example, an RF signal). The second node 214 comprises a three-port node coupled to an output node 218 for driving a downstream load (for example, an RF antenna section).

The high-power amplification path 220 of the illustrated embodiment comprises one or more transistors (for example, two or more parallel-coupled HBTs). The low-power amplification path 230 of the illustrated embodiment comprises a common-base transistor 234 (for example, a common-base HBT) coupled in series with a common-emitter transistor 236 (for example, a common-emitter HBT). In this particular configuration, the common-base transistor 234 is coupled upstream of the common-emitter transistor 236. Further, although only a single transistor combination is shown, the low-power amplifier subsection 232 may actually comprise two or more transistor combinations coupled in parallel. Still further, additional transistor stages may be included along the low-power amplification path 230.

The amplifier section 200 further comprises a first impedance matching network 240 coupled between the second node 214 and the output node 218. The first impedance matching network 240 of the illustrated embodiment is configured to provide substantially an impedance match between the output of the second node 214 during high-power operation. The amplifier section 200 further comprises a second impedance matching network 242 coupled between the second node 214 and the output of the low-power amplifier subsection 232. In the illustrated embodiment, the second impedance matching network 242 is configured to operate substantially as an impedance inverter. For example, the second impedance matching network 242 can have a characteristic impedance that produces substantially an impedance match with the load driven at the output node 218 when the low-power amplifier subsection 232 is enabled and the high-power amplifier subsection 222 is disabled. In some embodiments, the second impedance matching network 242 is implemented as a quarter-wavelength transmission line. In other embodiments, the second impedance matching network is implemented using lumped circuit equivalents (for example, combinations of capacitance and inductance elements).

A bias control system 250 operates the amplifier section 200 in multiple power modes. In the illustrated embodiment, for instance, the amplifier section 200 is operable in a high-power mode or a low-power mode in response to a control signal (“HIGH/LOW”) at a control node 260. In the low-power mode, (for example, when the HIGH/LOW signal is low), the bias control system 250 provides a bias voltage to the high-power amplifier subsection 222 via control line 252 that disables the high-power amplifier subsection. For example, a DC bias voltage can be supplied by the control line 252 to create a base-emitter voltage that causes one or more of the transistors of the amplifier subsection 222 to operate in the cut-off region, thereby disabling power amplification in the subsection. Also in the low-power mode, the bias control system 250 provides bias voltages to the low-power amplifier subsection 232 via control lines 254, 256 that enable the amplifier subsection. For example, a DC bias voltage can be applied via control line 254 to the common-emitter transistor 236 and another DC bias voltage can be applied via control line 256 to the common-base transistor 234 that create respective base-emitter voltages that cause the transistors to operate in the active region.

As noted, the second impedance matching network 242 of this embodiment operates substantially as an impedance inverter. The impedance matching network 242 can also provide a relatively high impedance at its upstream end during low-power-mode operation so that the low-power amplifier subsection 232 operates efficiently. For instance, in one particular embodiment, the first impedance matching network 240 is configured to transform a 50 Ohm load at output node 218 into 4 Ohms, and the second impedance matching network 242 is configured to transform the impedance seen at the second node 214 back into 50 Ohms during low-power operation. In other embodiments, however, the second impedance matching network 242 produces other desirably high impedances at its upstream end during low-power operation (for example, impedances that are substantially equal to or higher than the load driven at the output node 218, or higher than the impedance at the upstream end of the first impedance matching network 240).

In the high-power mode, (for example, when the HIGH/LOW signal is high), the bias control system 250 provides a bias voltage to the high-power amplifier subsection 222 via control line 252 that enables the high-power amplifier subsection 222. For example, a DC bias voltage can be supplied by the control line 252 that creates a base-emitter voltage in one or more of the transistors of the high-power amplifier subsection 222 that causes the transistors to operate in the active region, thereby enabling power amplification of the input signal on the high-power amplification path 220. Also in the high-power mode, the bias control system 250 provides bias voltages to the low-power amplifier subsection 232 via control lines 254, 256 that disable the low-power amplifier subsection. In certain implementations, the bias voltages provided on the control line 254, 256, and the resulting operation of the transistors 234, 236 help isolate the low-power amplification path 230 such that it does not interfere with the high-power amplification path 220. For example, according to one particular implementation, a DC bias voltage is applied via control line 256 to the common-base transistor 234 such that the transistor operates in the cut-off region. Additionally, a DC bias voltage is applied via control line 254 to the common-emitter transistor 236 such that the transistor operates in saturation mode. In this implementation, the impedance at the upstream end of the second impedance matching network 242 is low (because the common-emitter transistor 234 provides a low-impedance path to ground while operating in saturation mode). Consequently, a high impedance appears at the downstream end of the second impedance matching network 242. Thus, the input signal from the input node 216 can be amplified through the first amplification path 220 with low signal loss into the second amplification path 230. The high impedance at the downstream end of the second impedance matching network 242 also increases the stability of the amplifier section 200 by helping to prevent loop oscillations that may result from feedback from the output of the amplifier subsection 222 through the second amplification path 230.

The illustrated amplifier section 200 further comprises a third impedance matching network 244 coupled between the first node 212 and the input of the high-power amplifier subsection 222. In one exemplary embodiment, the third impedance matching network 244 is configured to substantially match the impedance at the input of the high-power amplifier subsection 222 with the impedance at the first node 212 during high-power operation.

The illustrated amplifier section 200 additionally comprises a fourth impedance matching network 246 coupled between the first node 212 and the input of the low-power amplifier subsection 232. In one exemplary embodiment, the fourth impedance matching network 246 is configured to substantially match the impedance at the input of the low-power amplifier subsection 232 with the impedance at the first node 212 during low-power operation.

It should be understood that the particular transistor configuration of the low-power amplifier subsection 232 illustrated in FIG. 2 is not to be construed as limiting, as other serial combinations of transistors are possible that enable the low-power amplifier subsection 232 to operate with high efficiency during low-power-mode operation and provide high reverse isolation and stability during high-power-mode operation. For example, a cascode configuration can be used or other combinations of common-emitter, common-base, and/or common-collector transistors (for instance, a common-emitter coupled in series with another common-emitter). Further, even though a single combination transistor configuration is shown in FIG. 2, multiple such configurations can be coupled in parallel to one another in the amplifier subsection 232.

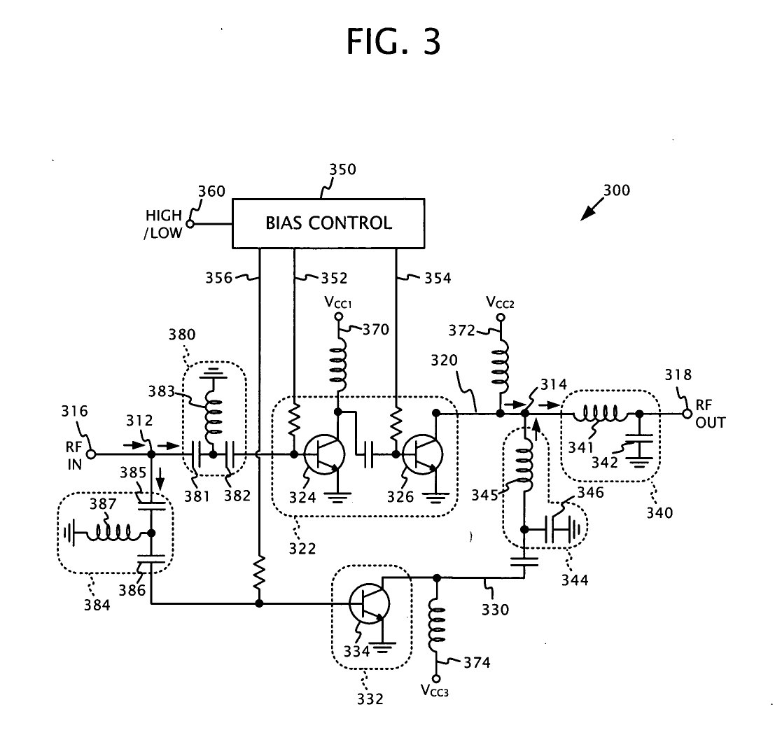

FIG. 3 is a schematic block diagram showing another specific implementation of the exemplary amplifier section 100 described above with respect to FIG. 1. In particular, FIG. 3 shows an amplifier section 300 comprising a high-power amplification path 320 coupled between a first node 312 and a second node 314, and a parallel low-power amplification path 330 also coupled between the first node 312 and the second node 314. In the illustrated embodiment, the first node 312 comprises a three-port node coupled to an input node 316 for receiving an input signal (for example, an RF signal). The second node 314 comprises a three-port node coupled to an output node 318 for driving a downstream load (for example, an RF antenna section).

The high-power amplification path 320 of the illustrated embodiment comprises a high-power amplifier subsection 322. The illustrated high-power amplifier subsection 322 comprises two amplifier stages: a first high-power transistor block 324 and a second high-power transistor block 326. In other embodiments, however, only a single transistor block is present on the high-power amplification path 320. For illustrative purposes only, the transistor blocks 324, 326 are shown as single transistors, though they can comprise two or more transistors (for example, two or more parallel-coupled HBTs). The low-power amplification path 330 of the illustrated embodiment comprises a single amplifier stage: a low-power transistor block 334. Even though FIG. 3 illustrates the low-power transistor block 334 as a single transistor, it can comprise two or more transistors (for example, two or more parallel coupled HBTs). Furthermore, any of the amplification paths 320, 330 can include multiple additional amplifier stages.

The amplifier section 300 further comprises a first impedance matching network 340 coupled between the second node 314 and the output node 318. In the illustrated embodiment, the first impedance matching network 340 comprises an inductance element 341 and a shunt capacitance element 342. The amplifier section 300 further comprises a second impedance matching network 344 between the second node 314 and the output of the low-power amplifier subsection 332. In the illustrated embodiment, the second impedance matching network 344 comprises an inductance element 345 and a shunt capacitance element 346.

In the illustrated embodiment, a bias control system 350 operates the amplifier subsection 300 in multiple power modes. In one exemplary embodiment, for instance, the amplifier section 300 operates in a high-power mode and a low-power mode in response to a control signal (“HIGH/LOW”) received at a control node 360. In the high-power mode, for instance, the bias control system 350 biases the high-power transistor blocks 324, 326 into active operation via control lines 352, 354 and biases the low-power transistor block 334 off via control line 356. Conversely, in the low-power mode, the bias control system 350 biases the high-power transistor blocks 324, 326 off and biases the low-power transistor block 334 into active operation.

In the illustrated embodiment, the first impedance matching network 340 is configured to provide substantially an impedance match between the output of the high-power amplifier subsection 322 and the load being driven at the output node 318 during high-power operation. Furthermore, in high-power operation, the high-power amplifier subsection 322 desirably drives a lower impedance load than that coupled to the output node 318 (this load is typically determined at least in part by the type of transistors used in the high-power amplifier subsection 322 and by how many of the transistors are coupled in parallel to one another). Accordingly, the first impedance matching network 340 commonly transforms a higher impedance at its downstream end into a lower impedance at its upstream end. By contrast, in low-power operation, the low-power amplifier subsection 332 desirably drives a higher impedance load than that driven by the high-power amplifier subsection 322 (again, this load is typically determined at least in part by the type of transistors used in the low-power amplifier subsection 332 and by how many of the transistors are coupled in parallel to one another). Accordingly, the second impedance matching network 344 commonly transforms a lower impedance at its downstream end into a high impedance at its upstream end. The increased impedance helps to improve the efficiency with which the low-power amplifier subsection 332 operates, thereby reducing power consumption in the low-power mode. In one particular implementation of the circuit section 300 in which the load at the output node 318 is 50 Ohms, for example, the first impedance matching network 340 and the second impedance matching network 344 are configured so that the high-power amplifier subsection 322 drives a 4Ohm load in high-power-mode operation and so that the low-power subsection 332 drives a 50 Ohm load in low-power-mode operation.

The illustrated amplifier section 300 further comprises a third impedance matching network 380 coupled between the first node 312 and the input of the high-power amplifier subsection 322. In the illustrated embodiment, the third impedance matching network 380 comprises two shunt capacitance elements 381, 382 and a series inductance element 383. The third impedance matching network 380 is further configured to substantially match the impedance at the input of the high-power amplifier subsection 322 with the impedance at the first node 312 during high-power operation and to transform the impedance at its downstream end into a higher impedance at its upstream end during low-power operation.

The illustrated amplifier section 300 additionally comprises a fourth impedance matching network 384 coupled between the first node 312 and the input of the low-power amplifier subsection 132. In the illustrated embodiment, the fourth impedance matching network 384 comprises two shunt capacitance elements 385, 386, and a series inductance element 387. The fourth impedance matching network 384 is also configured to substantially match the impedance at the input of the low-power amplifier subsection 332 with the impedance at the first node 312 during low-power operation and to transform the impedance at its downstream end into a higher impedance at its upstream end during high-power operation.

Also shown in FIG. 3 are respective voltage supply lines 370, 372, 374 coupled respectively to the first high-power transistor block 324, the second high-power transistor block 326, and the low-power transistor block 334. The respective voltage supply lines 370, 372, 374 receive respective supply voltages V_{CC1}, V_{CC2}, and V_{CC3}, at associated voltage supply nodes and apply the voltages to the respective collectors of the illustrated transistor blocks 324, 326, 334. In this way, the desired collector-emitter voltages of the transistor blocks 324, 326, 334 are established.

The particular configuration described above should not be construed as limiting, however, as several different alternative configurations are possible. For instance, in another embodiment, the bias control system 350 operates to bias the high-power amplifier subsection 322 into active operation and to bias at least some of transistors in the low-power amplifier subsection 332 into saturation during high-power mode. In this embodiment, the second impedance matching network 344 and the fourth impedance matching network 384 can be configured to operate substantially as impedance inverters. Thus, the low impedance resulting from operating transistors in the low-power amplifier subsection 332 in the saturation region is transformed into a high impedance at the downstream end of the second impedance matching network 344 and into a high impedance at the upstream end of the fourth impedance matching network 384. Consequently, the low-power path 330 has little or substantially no effect on the high-power amplification of path 320, and a signal being amplified along the high-power amplification path 320 has little or no insertion loss into the low-power amplification path 330. The high-power amplifier subsection 322 can be similarly operated. Depending on the implementation, any one of the transistor blocks 324, 326, 334 can be implemented using one or more of the combination transistor configurations described above with respect to FIG. 2 (for example, a common-base common-emitter configuration, common-base common-emitter configuration, common-emitter common-emitter configuration, or cascode configuration).

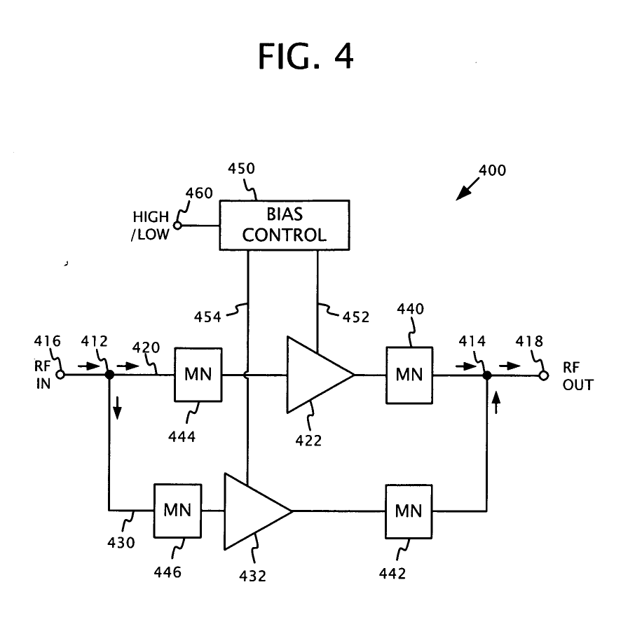

FIG. 4 is a schematic block diagram showing another exemplary amplifier section. In this embodiment, the impedance matching network on the low-power amplification path is coupled directly to the output node of the amplifier section. In particular, FIG. 4 shows an amplifier section 400 comprising a high-power amplification path 420 coupled between a first node 412 and a second node 414, and a parallel low-power amplification path 430 also coupled between the first node 412 and the second node 414. In the illustrated embodiment, the first node 412 is coupled to an input node 416 for receiving an input signal (for example, an RF signal). The second node 414 is coupled to an output node 418 for driving a downstream load (for example, an RF antenna section).

The high-power amplification path 420 of the illustrated embodiment comprises a high-power amplifier subsection 422. The high-power amplifier subsection 422 can comprise, for example one or more transistors (for example, multiple HBTs coupled in parallel). The low-power amplification path 430 of the illustrated embodiment comprises a low-power amplifier subsection 432. The low-power power amplifier subsection 432 can also comprise one or more transistors (for example, multiple HBTs coupled in parallel) and is typically configured to produce a lower power output than the high-power amplifier subsection 422. The high-power amplifier subsection 422 and the low-power amplifier subsection 432 can comprise any of the amplifier arrangements described above with respect to FIGS. 1 and 2.

The amplifier section 400 further comprises a first impedance matching network 440 coupled between the output of the high-power amplifier subsection 422 and the second node 414. In this embodiment, a second impedance matching network 442 is coupled between the output of the low-power amplifier subsection 432 and the second node 414. Thus, in this particular embodiment, the second impedance matching network 442 is coupled directly to the output node 418.

The illustrated amplifier section 400 further comprises a third impedance matching network 444 coupled between the first node 412 and the input of the high-power amplifier subsection 422. In the illustrated embodiment, the third impedance matching network 444 is configured to substantially match the impedance at the input of the high-power amplifier subsection 422 with the impedance at the first node 412 during high-power operation.

The illustrated amplifier section 400 additionally comprises a fourth impedance matching network 446 coupled between the first node 412 and the input of the low-power amplifier subsection 432. In the illustrated embodiment, the fourth impedance matching network 446 is configured to substantially match the impedance at the input of the low-power amplifier subsection 432 with the impedance at the first node 412 during low-power operation.

In the illustrated embodiment, a bias control system 450 operates the amplifier subsection 400 in multiple power modes. In one exemplary embodiment, for instance, the amplifier section 400 operates in a high-power mode and a low-power mode in response to a control signal (“HIGH/LOW”) received at a control node 460. In the high-power mode, for instance, the bias control system 450 enables the high-power amplifier subsection 422 via control line 452 and disables the low-power amplifier subsection 432 via control line 454. In the low-power mode, the bias control system 450 disables the high-power amplifier subsection 422 and enables the low-power amplifier subsection 432.

The impedance matching networks 440, 442, 444, 446 can be configured to perform a variety of different impedance transformations depending on the implementation. For example, in one exemplary implementation, at least the first and second impedance matching networks 440, 442 are configured to operate substantially as impedance inverters (for instance, substantially in accordance with the equation Z_{O}²=Z_{IN}×Z_{OUT}). Furthermore, the high-power amplifier subsection 422 and the low-power amplifier subsection 432 of this exemplary implementation comprise transistors or serial combinations of transistors wherein at least one of the transistors is operated in saturation mode when the respective high- or low-power amplifier subsection 422, 432 is disabled. For example, any of the configurations discussed above with respect to amplifier subsection 232 in FIG. 2 can be used. For example, in one particular implementation, the high- and low-power amplifier subsections 422, 432 comprise one or more common-base common-emitter configurations. In high-power mode, the common-base common-emitter configurations of the high-power amplifier subsection 422 are biased into active operation whereas the common-base transistors of the low-power amplifier subsection 432 are biased off while the common-emitter transistors of the low-power amplifier subsection 422 are biased into saturation mode. Consequently, the low impedance at the output of the low-power amplifier subsection 432 is transformed into a high impedance at the downstream end of the second impedance matching network 442. Because of this high impedance, the low-power amplification path 430 does not substantially interfere with amplification in the high-power amplification path 420. The characteristic impedance of the first impedance matching network 440 is further selected to achieve the desired impedance match between the output of the high-power amplifier subsection 422 and the output node 418 during high-power-mode operation.

Correspondingly, in low-power mode, the common-base common-emitter configurations of the low-power amplifier subsection 432 are biased into active operation whereas the common-base transistors of the high-power amplifier subsection 422 are biased off while the common-emitter transistors of the high-power amplifier subsection 422 are biased into saturation mode. Consequently, the low impedance at the output of the high-power amplifier subsection 422 is transformed into a high impedance at the downstream end of the first impedance matching network 440, and the high-power amplification path 420 does not substantially interfere with amplification in the low-power amplification path 430. The characteristic impedance of the second impedance matching network 442 is further selected to produce the desired impedance at its upstream end during low-power-mode operation.

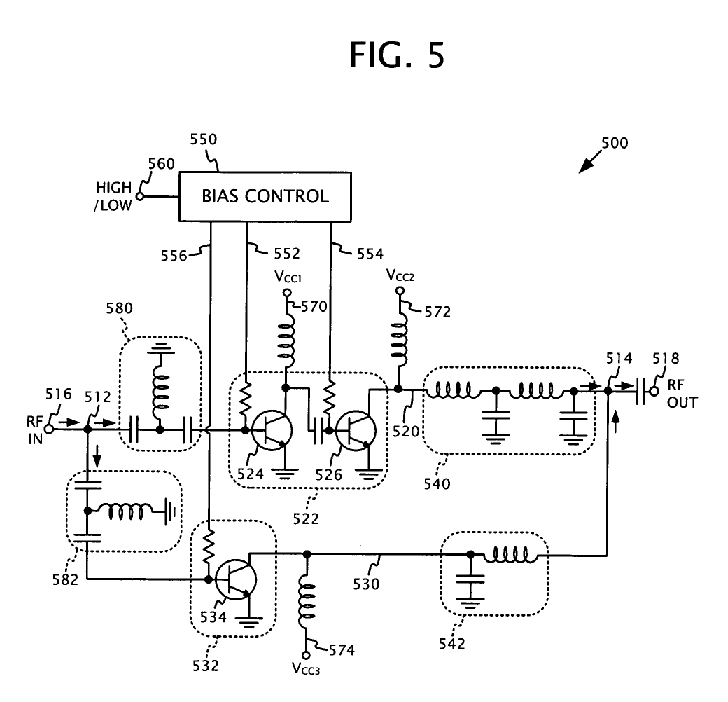

FIG. 5 is a schematic block diagram showing a more specific implementation of the exemplary amplifier section 400 described above with respect to FIG. 4. In particular, FIG. 5 shows an amplifier section 500 comprising a high-power amplification path 520 coupled between a first node 512 and a second node 514, and a parallel low-power amplification path 530 also coupled between the first node 512 and the second node 514. In the illustrated embodiment, the first node 512 is coupled to an input node 516 for receiving an input signal (for example, an RF signal), and the second node 514 is coupled to an output node 518 for driving a downstream load (for example, an RF antenna section).

The high-power amplification path 520 of the illustrated embodiment comprises a high-power amplifier subsection 522. The illustrated amplifier subsection 522 comprises two amplifier stages: a first high-power transistor block 524 and a second high-power transistor block 526. For illustrative purposes only, the transistor blocks 524, 526 are shown as single transistors, though they can comprise two or more transistors (for example, two or more parallel-coupled HBTs), serial combinations of transistors, or both. The low-power amplification path 530 of the illustrated embodiment comprises a single amplifier stage: low-power transistor block 534. Even though FIG. 5 illustrates the low-power transistor block 534 as a single transistor, it can comprise two or more transistors (for example, two or more parallel-coupled HBTs), serial combinations of transistors, or both.

The amplifier section 500 further comprises a first impedance matching network 540 coupled between the output of the high-power amplifier subsection 522 and the second node 514. In the illustrated embodiment, the first impedance matching network 540 comprises two inductance elements and two shunt capacitance elements. The amplifier section 500 further comprises a second impedance matching network 542 between the output of the low-power amplifier subsection 532 and the second node 514. Thus, the second impedance matching network 542 is the only impedance matching network interposed between the low-power amplifier subsection 532 and the output node 518. In the illustrated embodiment, the second impedance matching network 542 comprises an inductance element and a shunt capacitance element.

The illustrated amplifier section 500 further comprises a third impedance matching network 580 coupled between the first node 512 and the input of the high-power amplifier subsection 522. In the illustrated embodiment, the third impedance matching network 580 comprises two shunt capacitance elements and a series inductance element. The illustrated amplifier section 500 further comprises a fourth impedance matching network 582 coupled between the first node 512 and the input of the low-power amplifier subsection 532. In the illustrated embodiment, the fourth impedance matching network 582 comprises two shunt capacitance elements and a series inductance element.

The particular configuration of the impedance matching networks 540, 542, 580, 582 should not be construed as limiting in any way, however, as various other components and configurations for realizing the networks are possible (for example, other combinations of inductance and capacitance elements).

In the illustrated embodiment, a bias control system 550 operates the amplifier subsection 500 in multiple power modes. In one exemplary embodiment, for instance, the amplifier section 500 operates in a high-power mode and a low-power mode in response to a control signal (“HIGH/LOW”) received at a control node 560. In the high-power mode, for instance, the bias control system 550 biases the respective high-power transistor blocks 524, 526 into active operation via control lines 552, 554 and biases the low-power transistor block 534 off via control line 556. Correspondingly, in the low-power mode, the bias control system 550 biases the respective high-power transistor blocks 524, 526 off and biases the low-power transistor block 534 into active operation.

According to one exemplary embodiment, the first impedance matching network 540 of the illustrated embodiment is configured to provide substantially an impedance match between the output of the high-power amplifier subsection 522 and the load being driven at the output node 518 during high-power operation. Similarly, the third impedance matching network 580 is configured to substantially match the impedance at the input of the high-power amplifier subsection 522 with the impedance at the first node 512 during high-power operation. Also during high-power operation, the second impedance matching network 542 is configured to provide a desirably high impedance at its downstream end (seen by the second node 514) and the fourth impedance matching network 582 is configured to provide a desirably high impedance at its upstream end (seen by the first node 512) such that the high-power path 520 is effectively isolated from the low-power path 530.

In low-power mode, the second impedance matching network 542 is configured to present a desirably high impedance load to the output of the low-power amplifier subsection 332. That is, the upstream end of the second impedance matching network 542 desirably has a relatively high impedance during low-power mode operation. For example, this impedance can be greater than or equal to the load at the output node 518. This high impedance load at the upstream end of the second impedance matching network 542 decreases the current through the low-power amplifier subsection 532, and thereby increases the efficiency of the low-power amplifier subsection 532. Also during low-power operation, the fourth impedance matching network 582 is configured to substantially match the impedance at the input of the low-power amplifier subsection 532 with the impedance at the first node 512. Further, in low-power mode, the first impedance matching network 540 is configured to provide a desirably high impedance at its downstream end (seen by the second node 514) and the third impedance matching network 580 is configured to provide a desirably high impedance at its upstream end (seen by the first node 512) such that the low-power path 530 is effectively isolated from the high-power path 520.

In one particular implementation of the illustrated embodiment, for example, the second impedance matching network 542 and the fourth impedance matching network 582 are configured to operate substantially as impedance inverters. In this implementation, one or more transistors of the low-power amplifier subsection 532 are operated in their saturation regions when the amplifier subsection is disabled. Thus, for example, the low impedance resulting from operating transistors in the low-power amplifier subsection 522 in the saturation region during high-power mode is transformed into a high impedance at the downstream end of the second matching network 542 and also into a high impedance at the upstream end of the fourth matching network 582. The low-power path 530 consequently has little or substantially no effect on signal amplification through the high-power path 520 during high-power operation. The high-power amplifier subsection 522 can be similarly configured such that the bias control system 550 operates to bias one or more transistors in the high-power amplifier subsection 522 into saturation during low-power mode (for example, common-emitter transistors coupled in parallel or in combination transistor configurations). In this embodiment, the first impedance matching network 540 and the third impedance matching network 580 can also be configured to operate substantially as impedance inverters. Thus, during low-power operation, the high-power path 520 can similarly have little or no effect on signal amplification through the low-power path 530.

Also shown in FIG. 5 are respective voltage supply lines 570, 572, 574 coupled respectively to the first high-power transistor block 524, the second high-power transistor block 526, and the low-power transistor block 534. The respective voltage supply lines 570, 572, 574 receive respective supply voltages V_{CC1}, V_{CC2}, and V_{CC3}, at associated voltage supply nodes and, for example, apply the voltages to the respective collectors of the transistors in the illustrated transistor blocks 524, 526, 534. In this way, the desired collector-emitter voltages of the transistor blocks 524, 526, 534 are established.

The particular arrangement shown in FIG. 5 and described above should not be construed as limiting, however, as several different alternative configurations are possible. For instance, any one of the transistor blocks 524, 526, 534 can be implemented using one or more of the transistor combinations described above with respect to FIG. 2 (for example, a common-base common-emitter configuration, common-base common-collector configuration, common-emitter common-emitter configuration, or cascode configuration).

Having illustrated and described the principles of the illustrated embodiments, it will be apparent to those skilled in the art that the embodiments can be modified in arrangement and detail without departing from such principles. For example, the described amplifier embodiments are illustrated as comprising two amplification paths, but can comprise additional parallel amplification paths. In such embodiments, the amplifier sections can be operable in additional power-level modes, such as a high-power, intermediate-power, and low-power mode. Similarly, any of the disclosed embodiments may include one or more additional and separately controllable amplification stages along the respective amplification paths. Further, one or more bypass paths can be used in any of the described embodiments. Further, the disclosed amplifier sections do not necessarily need to operate as linear amplifiers when enabled, but may be operated as other types of amplifiers (for example, saturated amplifiers). Moreover, although several of the disclosed embodiments utilize bias toggling to control respective amplifier subsections, other means of selectively enabling and disabling the amplifier subsections can be used. For instance, in embodiments using bipolar junction transistors (BJTs) in the amplifier subsections, the collector-to-emitter voltages of the BJTs can be selectively controlled in order to enable (or increase the gain of) and disable (or decrease the gain of) the respective amplifier subsections. Equivalently, in embodiments using field-effect transistors, the drain-to-source voltages can be selectively controlled. Further, the number and location of the impedance matching networks as shown and described herein should not be construed as limiting, as this may vary from implementation to implementation. Likewise, the particular configurations of the control signals described herein should not be construed as limiting. Instead, the control signals can be configured to operate the amplifiers subsections in various other combinations and subcombinations with one another. For example, the amplifier subsections or any of the transistors that are contained therein can be independently controllable.

In view of the many possible embodiments, it will be recognized that the illustrated embodiments include only examples and should not be taken as limiting the scope of the disclosed technology. I therefore claim all such embodiments and their equivalents that come within the scope of the appended claims.

I claim:

1. An amplifier circuit, comprising:
a first amplification path coupled between a first node and a second node, the first amplification path comprising a high-power amplifier section;
a second amplification path coupled between the first node and the second node, the second amplification path comprising a low-power amplifier section and a low-power impedance transformation network coupled between the second node and the output of the low-power amplifier section; and
a control system coupled to and configured to selectively bias the high-power amplifier section and the low-power amplifier section,
the control system being operable in a low-power mode whereby the high-power amplifier section is disabled and the low-power amplifier section is enabled, and in a high-power mode whereby the high-power amplifier section is enabled and the low-power amplifier section is disabled.

2. The amplifier circuit of claim 1, wherein the impedance transformation network is configured to operate substantially as an impedance inverter.

3. The amplifier circuit of claim 1, wherein the second node is coupled to an output node configured to drive a downstream load; and
wherein the low-power impedance transformation network is configured to provide an impedance at its upstream end that is greater than or substantially equal to the downstream load when the amplifier circuit is operating in the low-power mode of operation.

4. The amplifier circuit of claim 1, wherein the first amplification path of the amplifier circuit further comprises a first amplification path impedance transformation network coupled between the second node and the output of the high-power amplifier section.

5. The amplifier circuit of claim 4, wherein the first amplification path impedance transformation network and the low-power impedance transformation network are both configured to operate substantially as impedance inverters.

6. The amplifier circuit of claim 1, wherein the second node is coupled to an output node that drives a downstream load; and
wherein the amplifier circuit further comprises an output path impedance transformation network coupled between the second node and the output node.

7. The amplifier circuit of claim 6, wherein the output path impedance transformation network is configured to provide a first impedance at its upstream end that is less than the downstream load; and
wherein the low-power impedance transformation network is configured to provide a second impedance at its upstream end that is greater than or substantially equal to the first impedance.

8. The amplifier circuit of claim 1, wherein at least one of the high-power amplifier section or the low-power amplifier section comprises one or more serial combinations of two or more transistors.

9. The amplifier circuit of claim 8, wherein the serial combinations of transistors comprise at least one of a common-base transistor in series with common-emitter transistor, a common-base transistor in series with a common-collector transistor, or a common-emitter transistor in series with another common-emitter transistor.

10. The amplifier circuit of claim 1, wherein at least one of the low-power amplifier section or the high-power amplifier section comprises a transistor that is operated in saturation mode when its associated amplifier section is disabled by the control system.

11. The amplifier circuit of claim 1, implemented in a power amplifier module for use in a mobile handset.

12. An electronic device comprising the amplifier circuit of claim 1.

13. An amplifier circuit comprising:
a first RF signal path comprising a first amplifier section that includes at least one transistor;
a second RF signal path coupled in parallel to the first RF signal path and comprising a second amplifier section that includes at least one transistor; and
a control system configured to operate the first amplifier section and the second amplifier section in a mode of operation whereby the at least one transistor of the first amplifier section is biased into its active region and wherein the at least one transistor of the second amplifier section is biased into its saturation region.

14. The amplifier circuit of claim 13, wherein the second RF signal path further comprises a matching network configured to operate substantially as an impedance inverter coupled to the output of the second amplifier section.

15. The amplifier circuit of claim 13, wherein the matching network is a first matching network, and wherein the second RF signal path further comprises a second matching network configured to operate substantially as an impedance inverter coupled to the input of the second amplifier section.

16. The amplifier circuit of claim 13, wherein the second amplifier section comprises two or more transistors coupled in series with one another.

17. The amplifier circuit of claim 16, wherein the two or more transistors coupled in series comprise at least one of a common-base common-emitter configuration, a common-base common-collector configuration, common-emitter common-emitter configuration, or a cascode configuration.

18. The amplifier circuit of claim 13, wherein the mode of operation is a high-power mode of operation; and
wherein the control system is further configured to operate the first amplifier section and the second amplifier section in a low-power mode of operation whereby at least one transistor of the first amplifier section is biased into its cut-off region and wherein at least one transistor of the second amplifier section is biased into its active region.

19. The amplifier circuit of claim 18, wherein the control system is configured to receive a single-bit control signal.

20. The amplifier circuit of claim 13, wherein the transistors of the first amplifier section and the second amplifier section comprise heterojunction bipolar transistors.

21. The amplifier circuit of claim 13, implemented on a single semiconductor substrate.

22. An electronic device comprising the amplifier circuit of claim 13.

23. An amplification method, comprising:
in a first amplifier mode, biasing a first transistor of a first amplifier section into the first transistor's active region and biasing a second transistor of a second amplifier section into the second transistor's saturation region, thereby providing a first gain to an RF signal; and
in a second amplifier mode, biasing the first transistor of the first amplifier section into the first transistor's saturation region and biasing the second transistor of the second amplifier section into the second transistor's active region, thereby providing a second gain to the RF signal.

24. The amplifier method of claim 23, further comprising, in the first amplifier mode, biasing a third transistor in the second amplifier section into the third transistor's cut-off region.

25. The amplifier method of claim 23, wherein the second amplifier section is disabled during the first amplifier mode and wherein the first amplifier section is disabled during the second amplifier mode.

26. An electronic device comprising two or more switchless amplification paths coupled in parallel to one another, the amplification paths respectively comprising amplifier sections that are activated substantially exclusively of one another, one of the amplification paths comprising an impedance transformation network coupled to the output of the respective amplifier section of the amplification path.

27. The electronic device of claim 26, wherein the impedance transformation network is an impedance inverter.

28. The electronic device of claim 26, wherein the electronic device is a mobile handset.

29. The electronic device of claim 26, wherein the amplifier sections of the amplification paths are configured to operate as linear amplifiers.

30. The electronic device of claim 26, wherein the two or more switchless amplification paths are implemented on a single chip.
